(19) United States
(12) Patent Application Publication
(10) Pub. No.: US 2006/0197445 A1
(43) Pub. Date: Sep. 7, 2006

(54) Self-emitting panel and method of manufacturing self-emitting panel

(75) Inventor: Teruichi Watanabe, Yamagata (JP)

Correspondence Address: FOLEY AND LARDNER LLP;SUITE 500, 3000 K STREET NW, WASHINGTON, DC, 20007, US

(73) Assignee: TOHOKU PIONEER CORPORATION

(21) Appl. No.: 11/366,605

(22) Filed: Mar. 3, 2006

(30) Foreign Application Priority Data
Mar. 4, 2005 (JP) 2005-061646

(51) Int. Cl. H05B 33/04; H05B 33/10

(52) U.S. Cl. 313/512; 313/503; 445/25

(57) ABSTRACT

In a self-emitting panel, self-emitting devices are arranged on a substrate in an array. Each self-emitting device includes a pair of electrodes and an emitting layer arranged between the electrodes. An insulating film insulates each of the self-emitting devices from others of the self-emitting devices on the substrate, by separating the emitting layer and at least one of the electrodes from those of the others. A sealing member is arranged to form a sealing region for shielding the self-emitting devices from the air, between the sealing member and the substrate. A sipe is provided at a portion beside an outermost self-emitting device arranged at an outermost part in the array such that the sipe is positioned closer to an edge of the substrate than the outermost self-emitting device is. The sipe has a depth in a direction of a thickness of the insulating film to divide the insulating film.

### BACKGROUND OF THE INVENTION

1. Field of the Invention

The present invention relates to a self-emitting panel and a method of manufacturing the self-emitting panel.

2. Description of the Related Art

Self-emitting panels using as organic electroluminescence (hereinafter, “EL”) device as a self-emitting device are increasingly used, for example, for display screens of various information equipments and illuminations such as lights.

For the organic EL devices, the moisture in the air is considered to be a factor of deterioration of the organic EL device. To prevent the deterioration of the organic EL device due to such factor, a sealing method is used for shielding the organic EL device from the air. One of the sealing methods is an air-tight sealing method. In this method, a sealing member is disposed oppositely to a substrate on which the organic EL device is provided such that a sealing region shielding the organic EL device from the air is formed between the sealing member and the substrate. Such a technology is disclosed in, for example, Japanese Patent Application Laid-Open Publication No. 2000-21567. With the air-tight sealing method, the self-emitting panel using the organic EL device can be easily manufactured at low cost.

FIG. 12 is a cross-section of a conventional self-emitting panel 1200. As shown in FIG. 12, the conventional self-emitting panel 1200 includes a substrate 1204 provided with plural self-emitting devices 1203. Each of the self-emitting devices 1203 includes an electrode pair 1201 and an emitting layer 1202 arranged between the electrode pair 1201. A sealing member 1206 is disposed oppositely to the substrate 1204 such that a sealing region 1205 is formed with the substrate 1204 to shield the self-emitting devices 1203 from the air.

The substrate 1204 is provided with an insulating film 1207 insulating an electrode 1201a, which is a part of the electrode pair 1201, from the emitting layer 1202, for each self-emitting device 1203. The substrate 1204 and the sealing member 1206 are bonded via an adhesive agent 1208. In this way, deterioration factors are prevented from entering into the sealing region 1205.

However, with the above conventional technology, when the organic EL device is used as the self-emitting device 1203, even if the substrate 1204 and the sealing member 1206 are bonded via the adhesive agent 1208, the moisture in the air may be delivered through the adhesive agent 1208 and may deteriorate the organic EL device.

### SUMMARY OF THE INVENTION

it is an object of the present invention to solve at least the above problems.

A self-emitting panel according to one aspect of the present invention includes a plurality of self-emitting devices arranged in an array and including a pair of electrodes; and an emitting layer arranged between the electrodes; a substrate on which the self-emitting devices are provided; an insulating film provided on the substrate, and configured to insulate each of the self-emitting devices from others of the self-emitting devices on the substrate, by separating a set of the emitting layer and at least one of the electrodes from each set of the emitting layer and at least one of the electrodes of the others; a sealing member arranged on the substrate such that a sealing region is formed between the sealing member and the substrate, the sealing region for shielding the self-emitting devices from the air; and a sipe provided on a surface of the substrate on which the self-emitting devices are arranged at a portion beside an outermost self-emitting device that is arranged at an outermost part in the array such that the sipe is positioned closer to an edge of the substrate than the outermost self-emitting device is, the sipe having a depth in a direction in which the substrate and the sealing member are opposed, to divide the insulating film.

A method according to another aspect of the present invention is of manufacturing a self-emitting panel. The method includes arranging a plurality of self-emitting devices on a substrate in an array, the self-emitting devices each including a pair of electrodes, and an emitting layer arranged between the electrodes; forming an insulating film on the substrate, the insulating film configured to insulate each of the self-emitting devices from others of the self-emitting devices on the substrate, by separating a set of the emitting layer and at least one of the electrodes from each set of the emitting layer and at least one of the electrodes of the others; forming a sipe on a surface of the substrate on which the self-emitting devices are arranged at a portion beside an outermost self-emitting device that is arranged at an outermost part in the array such that the sipe is positioned closer to an edge of the substrate than the outermost self-emitting device is, the sipe having a depth in a direction of a thickness of the insulating film, to divide the insulating film; and forming a sealing region for shielding the self-emitting devices from the air, between a sealing member and the substrate by providing the sealing member on the substrate.

### BRIEF DESCRIPTION OF THE DRAWINGS

FIG. 1 is a plan view of a self-emitting panel according to an embodiment of the present invention;

FIG. 2 is a cross-section of the self-emitting panel;

FIG. 3 is a cross-section of a self-emitting panel according to another embodiment of the present invention;

FIG. 4 is a cross-section of a self-emitting panel according to another embodiment of the present invention;

FIG. 5 is a cross-section of a self-emitting panel according to another embodiment of the present invention;

FIG. 6 is a schematic for illustrating a process of forming a film of an electrode material;

FIG. 7A is a top view for illustrating a process of patterning of a metal conductive film;

FIG. 7B is a top view for illustrating the process of patterning of a metal conductive film;

FIG. 8A is a top view for illustrating a process of patterning of a transparent conductive film;

FIG. 8B is a cross-section for illustrating the process of patterning of a transparent conductive film;

FIG. 9A is a top view for illustrating a process of forming an insulating film;

FIG. 9B is a cross-section for illustrating the process of forming an insulating film;

FIG. 10 is a schematic of an evaporation apparatus used at a film forming process;

FIG. 11A is a cross-section of a self-emitting panel according to another embodiment of the present invention;

FIG. 11B is a cross-section for illustrating a process of forming a thin-film transistor (TFT);

FIG. 11C is a cross-section for illustrating a process of forming a lower electrode;

FIG. 11D is a cross-section for illustrating a process of forming an insulating film; and

FIG. 12 is a cross-section of a conventional self-emitting panel.

### DETAILED DESCRIPTION OF THE PREFERRED EMBODIMENTS

Exemplary embodiments according to the present invention will be explained in detail below with reference to the accompanying drawings.

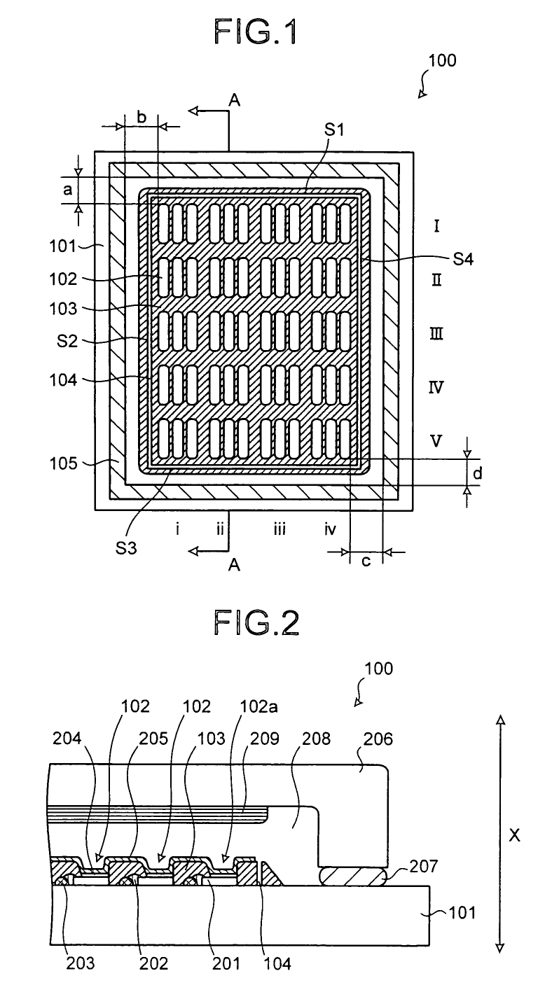

FIG. 1 is a plan view of a self-emitting panel according to an embodiment of the present invention. A self-emitting panel 100 includes self-emitting devices 102 provided on a substrate 101. The self-emitting device 102 is realized by an organic EL device.

The organic EL device is configured by stacking a plurality of layers having various functions. The stacked-layer configuration of each layer in the organic EL device generally has a configuration such that the layers are stacked in the order of “lower electrode (anode), hole injection layer, hole transporting layer, emitting layer (organic EL layer), electron transporting layer, electron injection layer, and upper electrode (cathode)”. The organic EL device may be formed in such a stacked-layer configuration or in a single-layer configuration.

Each layer of the organic EL device may be a low-molecular organic material or high-molecular organic material, may be formed by a single organic material, may be formed by mixing a plurality of materials (mixed layer), or may be formed by dispersing organic or inorganic functional materials in a high-molecular binder. The functional materials may include an electron transporting function, an emitting function, a locking function, an optical function, etc.

Each layer of the organic EL device may include a layer having a buffer function for avoiding damages of the emitting layer when the electrode is formed on the upper side of the emitting layer or a planarization function for preventing unevenness of a surface of the emitting layer from occurring due to a film forming process of the emitting layer.

Additionally, the organic EL device may have an anode that is an electrode located on the upper side of the emitting layer and a cathode that is an electrode located on the lower side of the emitting layer, may have the emitting layer formed in multiple layers, may be formed by stacking emitting layers having different luminescent colors, which is a stacked organic light emitting device (SOLED), may have an electron generation layer (not shown) between the cathode and the anode (a multi-photon device), may not have a layer such as the hole transporting layer, may have the layer formed by stacking a plurality of layers, or may have a device configuration formed only by a single organic layer (with functional layers formed sequentially or with layer boundaries eliminated). In the embodiment, the configuration of the organic EL device is not limited.

With regard to the self-emitting devices 102, all the self-emitting devices 102 may be display devices of the self-emitting panel 100 or a portion of the self-emitting devices 102 may be a monitor devices. The display device is the self-emitting device 102 used for information display such as characters, symbols, images, and videos displayed by the self-emitting panel 100 or for display such as illumination or various interior accessories. The monitor device is the self-emitting device 102 not used for the display described above. More particularly, the monitor device may be used for obtaining parameters relating to the drive of the self-emitting device 102.

The parameters obtained from the self-emitting device 102 functioning as the monitor device are fed back to each display device when the self-emitting device 102 playing a role of the display device is driven. The parameters relating to the drive of the self-emitting device 102 include a drive voltage, current, luminance, etc. The monitor device is formed by using the outermost self-emitting device in an array surface of the self-emitting devices 102.

Each of the self-emitting devices 102 is insulated by an insulating film 103. The insulating film 103 is provided so as to cover the entire array surface or a circumferential portion of the array surface of the self-emitting devices 102. The insulating film 103 is provided with a sipe 104 such as a slit or groove, which is defined as a “sipe” in the embodiment of the present invention. As described later, the sipe 104 of the embodiment is provided sequentially so as to surround the circumference of the array surface of the self-emitting devices 102. The insulating film 103 is formed by using materials such as polyimide, acrylic, and SiO₂. Although the sipe is formed to be hollow in the description of the embodiment, the sipe may be filled with a material delaying the delivery of the deterioration factor, such as ITO.

On the substrate 101, a bonding area 105 surrounding the outside of the insulating film 103 is reserved for applying an adhesive agent (207 of FIG. 2) bonding a sealing member (206 of FIG. 2) and the substrate 101. Although not shown in FIG. 1, the sealing member is disposed oppositely to the substrate 101 to form a sealing region (208 of FIG. 2) with the substrate 101, shielding the self-emitting devices 102 from the air.

Distances a, b, c, and d shown in FIG. 1 show distances from the outermost self-emitting devices 102 in the array surface of the self-emitting devices 102 to the bonding area 105. In FIG. 1, symbols I, II, III, IV, V, i, ii, iii, and iv are symbols added for convenience to show a position of each self-emitting device 102 in the array surface of the self-emitting devices 102. In FIG. 1, symbols S1, S2, S3, and S4 are symbols added for convenience to show a position of the sipe 104 in the array surface of the self-emitting devices 102.

FIG. 2 is a cross-section of the self-emitting panel 100. FIG. 2 shows the self-emitting panel 100 shown in FIG. 1 cut along a line A-A and viewed laterally. As shown in FIG. 2, the self-emitting panel 100 is provided with a plurality of self-emitting devices 102 on one side of the substrate 101. Although the configuration of the organic EL device playing a role of the self-emitting device 102 is not limited as described above, in FIG. 2, the organic EL device shown as the self-emitting device 102 includes a TFT 203 including a drain electrode 202, and a lower electrode 201, organic layers 204, and an upper electrode 205. The drain electrode 202 and the lower electrode 201 are connected directly or via another conductive material and on/off of the self-emitting device 102 are controlled by the TFT 203.

In the embodiment, the upper electrode 205 is in common among all the self-emitting devices 102 and is provided to form a single electrode layer covering all the self-emitting devices 102. An electrode pair is realized by the lower electrode 201 and the upper electrode 205. Although not shown, the upper electrode 205 may be sectioned and divided by partitions.

The lower electrode 201 is connected to an anode of a power source to apply a positive voltage to the corresponding organic layers 204 and the upper electrode 205 is grounded. An electric current is supplied to the self-emitting device 102 from the drain electrode 202 of the TFT 203 via the connected lower electrode 201.

Although an example of a drive device for the active drive of the self-emitting device 102 is shown by the self-emitting panel 100 of the embodiment, the number and the circuit configuration of the TFT 203 and a driving method such as a constant-voltage drive and constant-current drive can be arbitrarily designed and selected depending on usage patterns of the self-emitting panel 100. Description is not made of details such as the configuration of the TFT 203 since this is a known technology.

The organic EL device is realized by stacking the organic layers 204 such as a hole injection layer, a hole transporting layer, an emitting layer, an electron transporting layer, and an electron injection layer between the lower electrode 201 and the upper electrode 205. The organic layers may be a single layer, and a high-molecular material or low-molecular material may be used.

The organic layers 204 may be formed by dispersing low-molecular materials and inorganic materials in a high-molecular material. The emitting material forming the emitting material can be arbitrarily designed and selected depending on usage patterns of the self-emitting panel 100 from a fluorescent material using luminescence (fluorescence) when returning to a ground state from a singlet excitation state, a phosphorescent material using luminescence (phosphorescence) when returning to a ground state from a triplet excitation state. Description is not made of details such as the configuration of the organic EL device since this is a known technology.

The sealing member 206 is provided on the side of the substrate 101 where the self-emitting devices 102 are provided. The sealing member 206 has a container shape with opening on one side and is provided such that all the self-emitting devices 102 are covered. The sealing member 206 is bonded to the substrate 101 via the adhesive agent 207. The sealing region is formed by the substrate 101, the sealing member 206, and the adhesive agent 207. The sealing member 206 is provided with a desiccant 209 at a position opposed to the self-emitting devices 102.

The sipe 104 is provided on the outside of the outermost self-emitting devices 102 in the array surface of the self-emitting devices 102. The sipe 104 of the embodiment is provided so as to penetrate the insulating film 103 along the direction opposed to the substrate 101 and the sealing member 206 (direction of an arrow X in FIG. 2).

The sipe 104 is not limited to the single sipe 104 and a plurality of the sipes 104 may be provided in the array surface of the self-emitting devices 102 along the outward direction. In this case, any number of the sipes 104 may exist. However, since it is conceivable that the bonding force between the insulating film 103 and the substrate is reduced as the number of the sipes 104 increases, the number of the sipes 104 is desired to be to the extent that the bonding force between the outermost portion of the insulating film 103 and the substrate 101 satisfies the required bonding force.

By the way, as seen from FIG. 1, a plurality of the self-emitting devices 102 correspond to the outermost self-emitting devices 102 (102a of FIG. 2) in the array surface of the self-emitting devices 102. Therefore, in some array patterns of the self-emitting devices 102, the outermost self-emitting devices 102 in the array surface of the self-emitting devices 102 may have different distances from the bonding area 105. Although not shown, in such a case, the sipe 104 may be provided at the outer side of the self-emitting device 102a provided at a position having a shortest distance from a bonding position of the substrate 101 and the sealing member 206, that is, the bonding area 105 in the array surface of the self-emitting devices 102.

For example, if the distances a, b, c, and d from the bonding area 105 shown in FIG. 1 have a relationship of a<b<c<d, the self-emitting devices 102 arranged in a row indicated by I are the self-emitting devices 102a provided at a position having a shortest distance from the bonding area 105 in the array surface of the self-emitting devices 102, and the sipe 104 indicated by the symbol S1 is provided.

The sipe 104 may be provided at the outer side of the self-emitting device 102a provided at a position having a distance from the bonding area 105 shorter than a predetermined distance among the outermost self-emitting devices 102a in the array surface of the self-emitting devices 102. The predetermined distance can be suitably set by comprehending a distance tending to be affected by the deterioration factors from experiments, etc.

For example, if the distances a, b, c, and d from the bonding area 105 shown in FIG. 1 have a relationship of a<b<c<r<d with respect to a predetermined distance r, the self-emitting devices 102 arranged in rows indicated by I, i, and iv are the self-emitting devices 102a provided at a position having a distance from the bonding area 105 shorter than the predetermined distance r, and the sipe 104 indicated by the symbols S1, S2, and S4 is provided to the self-emitting devices 102 arranged in rows indicated by I, i, and iv.

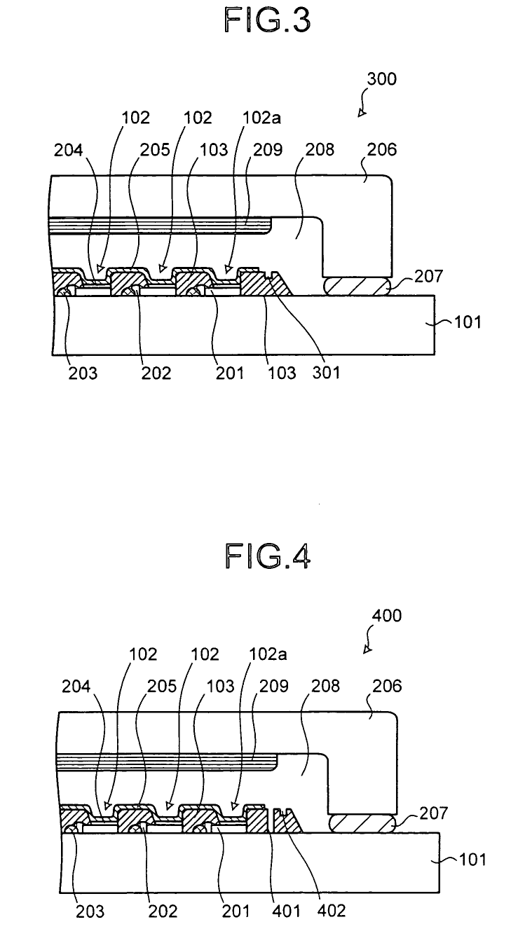

FIG. 3 is a cross-section of a self-emitting panel according to another embodiment of the present invention. In a self-emitting panel 300 shown in FIG. 3, a shape of a sipe 301 provided in the insulating film 103 is different from the self-emitting panel 100 shown in FIGS. 1 and 2 described above. The sipe 301 of the self-emitting panel 300 shown in FIG. 3 is provided so as to partially divide the insulating film 103 in the direction opposed to the substrate 101 and the sealing member 206. In the self-emitting panel 300 of another embodiment, the same symbols are added to the same portions as the self-emitting panel 100 shown in FIGS. 1 and 2 and description thereof is omitted. The same applies to the following figures.

FIG. 4 is a cross-section of a self-emitting panel according to another embodiment of the present invention. A self-emitting panel 400 shown in FIG. 4 is provided with two sipes in the direction opposed to the substrate 101 and the sealing member 206, which are a first sipe 401 provided so as to penetrate the insulating film 103 along the opposed direction and a second sipe 402 provided so as to partially divide the insulating film 103. The second sipe 402 is provided at the outer side of the first sipe 401 along the outward direction in the array surface of the self-emitting devices 102.

FIG. 5 is a cross-section of a self-emitting panel according to another embodiment of the present invention. A self-emitting panel 500 shown in FIG. 5 is provided with two sipes in the direction opposed to the substrate 101 and the sealing member 206, which are a first sipe 501 provided so as to partially divide the insulating film 103 and a second sipe 502 provided so as to penetrate the insulating film 103 along the opposed direction. The second sipe 502 is provided at the outer side of the first sipe 501 along the outward direction in the array surface of the self-emitting devices 102.

When a plurality of sipes (e.g., the first sipe 401 and the second sipe 402 or the first sipe 501 and the second sipe 502) are provided in the outward direction of the array surface of the self-emitting devices 102, all the sipes may have the same shape or each sipe may have different shape. When a plurality of sipes are provided in the outward direction of the array surface of the self-emitting devices 102, preferably, at least one sipe penetrates the insulating film 103 along the direction opposed to the substrate 101 and the sealing member 206.

Since the monitor device is used for obtaining the parameters relating to the drive of the self-emitting device 102, the deterioration of the monitor device causes the defective display of the self-emitting panel. In the self-emitting panels 100, 300, 400, 500 of the embodiment, by preventing the deterioration of the monitor device, the display qualities of the self-emitting panels 100, 300, 400, 500 can be prevented form being deteriorated.

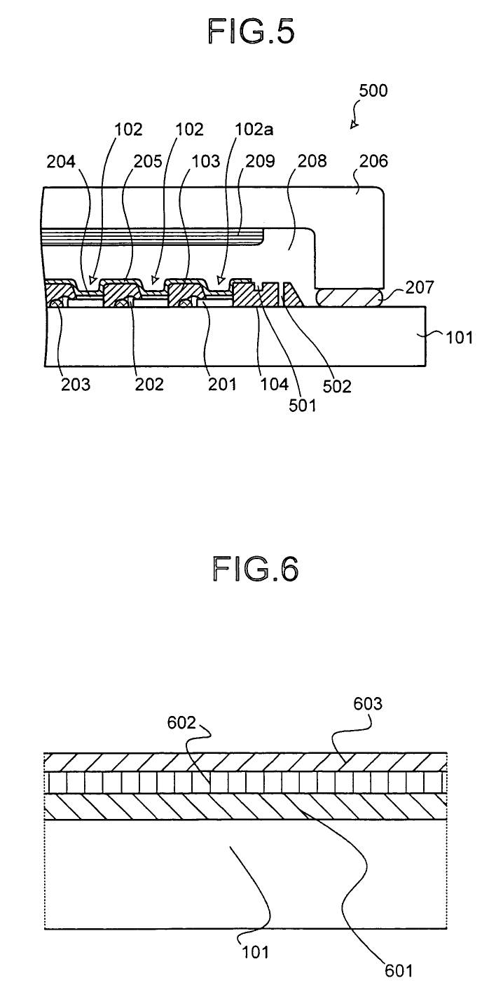

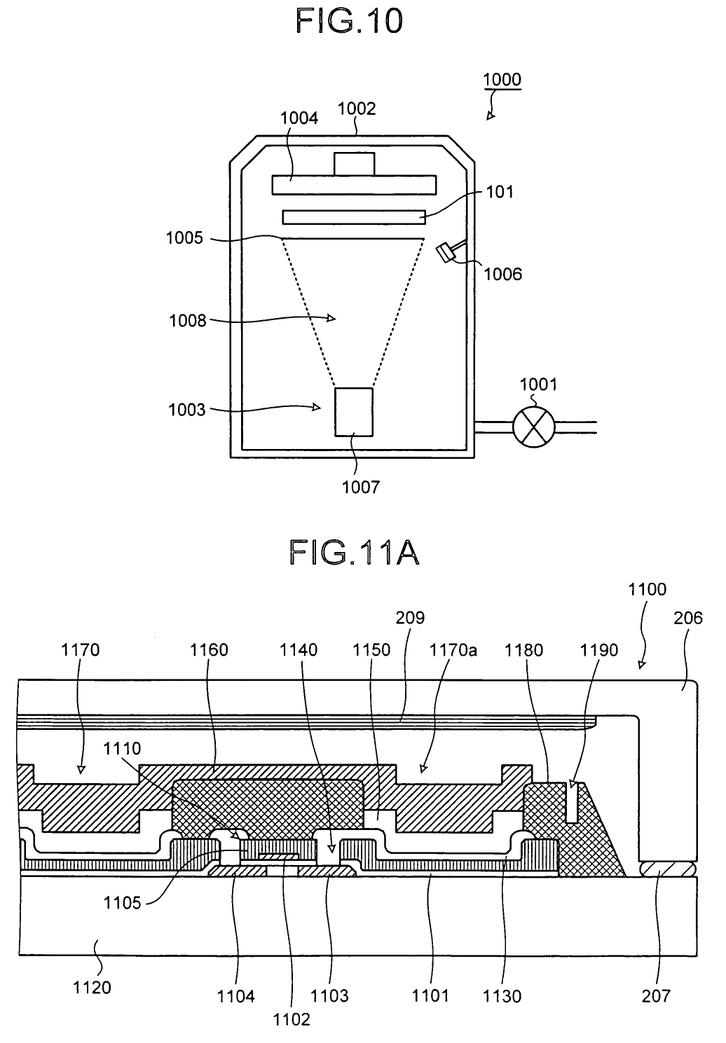

The manufacturing process of the self-emitting panel 100 is composed of a preprocessing step, a film forming step using an evaporation apparatus (see FIG. 10), and a sealing step using the sealing member 206. The preprocessing step includes an electrode material film forming step, metal conductive film patterning step, a transparent conductive film patterning step, and an insulating film forming step (see FIGS. 6 to 9).

FIG. 6 is a schematic for illustrating a process of forming a film of the electrode material. At the electrode material film forming step, the substrate 101 with films is prepared and the films are formed in the order of a buffer layer 601, a transparent conductive film 602, and a metal conductive film 603. In general, glass or plastic is used for the substrate 101. In general, SiO₂ (silicon dioxide), TiO₂ (titanium oxide), etc. are used for the buffer layer 601. In general, ITO (indium tin oxide), IZO (indium zinc oxide), etc. are used for the transparent conductive film 602. In general, Cr (chromium), Al (aluminum), Ag (silver), etc. are used for the metal conductive film 603. The buffer layer 601, the transparent conductive film 602, and the metal conductive film 603 are formed by a method such as sputtering, evaporation, spin-coating, dip coating, and application.

The most preferable example is a formation example using glass for the substrate 101, using ITO for the transparent conductive film 602, and using Al for the metal conductive film 603. When glass including an alkaline component is used for the substrate 101, if the glass contains impure elements (such as alkali metals, Ca, and Na), the buffer layer 601 is used for blocking the permeation of the impure elements.

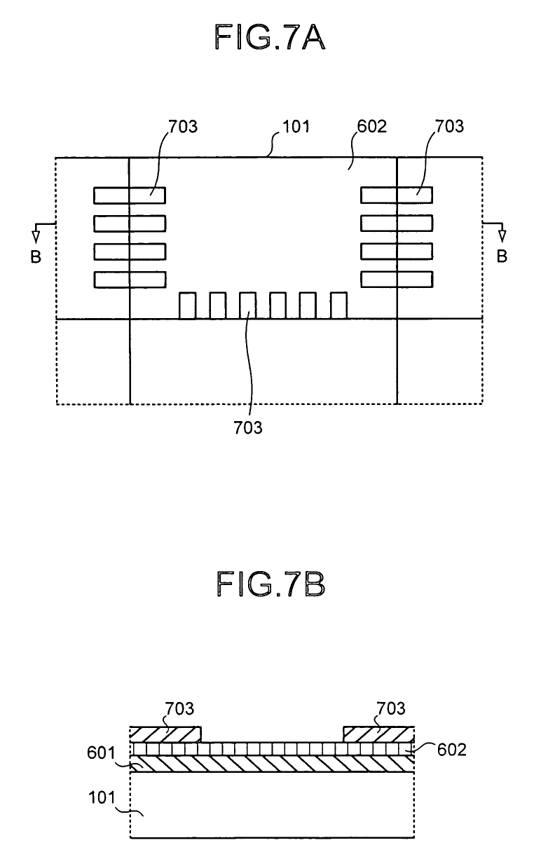

FIG. 7A is a top view o for illustrating the process of patterning of a metal conductive film. FIG. 7B is a cross-section for illustrating the process. FIG. 7B shows a state when viewed laterally after cutting along a line B-B of FIG. 7A. Among the buffer layer 601, the transparent conductive film 602, and the metal conductive film 603 formed on the substrate 101 at the electrode material film forming step, lead-out wirings of the lower electrode and upper electrode are patterned on the uppermost metal conductive film 603 using the photolithography method to form a metal conductive film portion 703 of the lead-out wiring pattern.

FIG. 7A shows the substrate 101 after patterning of the metal conductive film portion 703 of the lead-out wiring pattern viewed from above. As shown in FIGS. 7A and 7B, the transparent conductive film 602 is exposed from the portions of the substrate 101 where the uppermost metal conductive film 603 is removed.

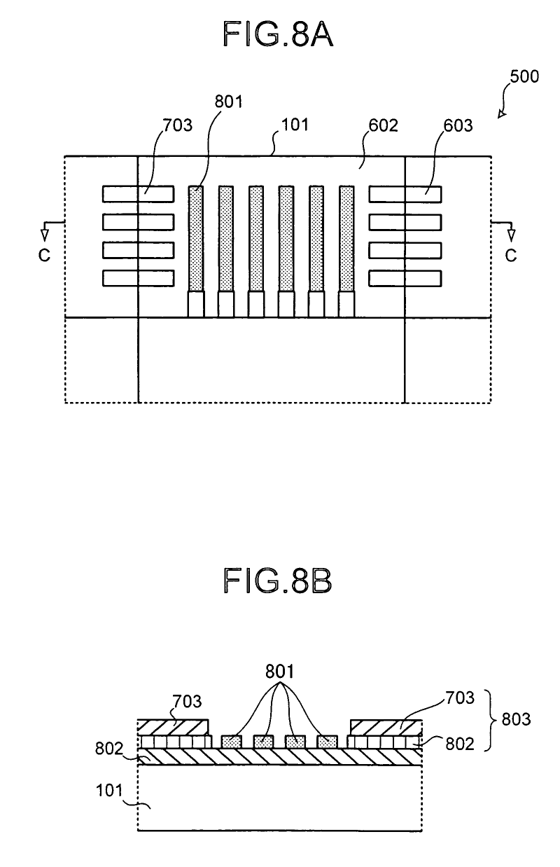

FIG. 8A is a top view for illustrating a process of patterning of a transparent conductive film. FIG. 8B is a cross-section for illustrating the process. FIG. 8B shows a state when viewed laterally after cutting along a line C-C of FIG. 8A. At a third step, patterning is performed for the transparent conductive film 602 exposed on the substrate 101 at the second step. With the patterning, all the exposed portions of the transparent conductive film 602 are removed except shaded portions 801 shown in FIG. 8A (lower electrode forming portions) and transparent conductive film portions 802 of the lead-out wiring pattern (the transparent conductive film 602 of the metal conductive film portion 703 of the lead-out wiring pattern). FIGS. 8A and 8B show the state of the substrate 101 after the patterning.

The lower electrodes 201 are formed by the shaded portions 801, and lead-out wirings 803 are formed by the metal conductive film portions 703 of the lead-out wiring pattern and the transparent conductive film portions 802 of the lead-out wiring pattern. The surfaces of the lower electrodes 201 may be smoothed by polishing the surfaces of the portions of the shaded portions 801 that will be the lower electrodes 201. The surfaces of the lower electrodes 201 may be smoothed by chemically etching the surfaces of the lower electrodes with the use of the etchant (etching liquid) used for forming the lower electrodes 201, which has a reduced density.

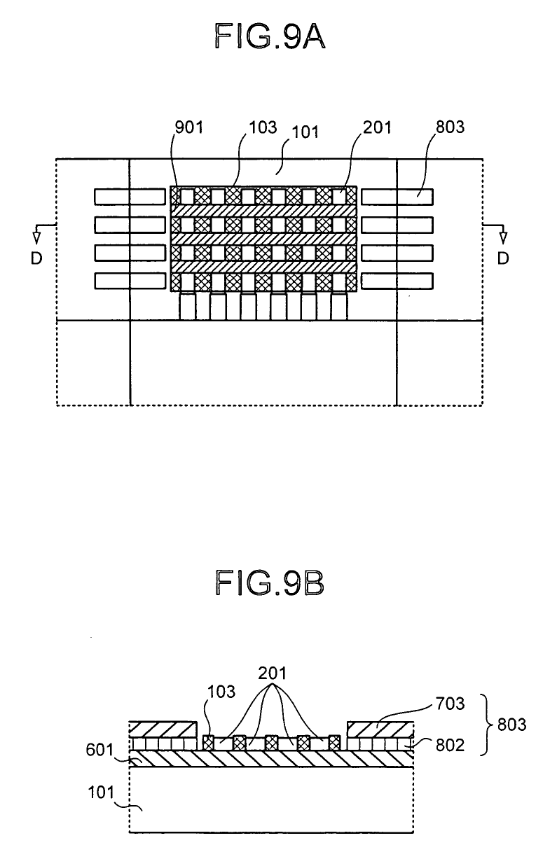

FIG. 9A is a top view for illustrating a process of forming an insulating film. FIG. 9B is a cross-section for illustrating the process. FIG. 9A shows a state after the patterning of the substrate 101 viewed from above. FIG. 9B shows a state when viewed laterally after cutting along a line D-D of FIG. 9A. At the insulating film forming step, an insulating film of photosensitive polyimid, etc. is patterned between the lines of the lower electrodes 201 with the use of the photolithography method. With this insulating film forming step, an insulating film is formed which insulates at least one electrode (the lower electrode 201 in the embodiment) of the electrode pair and an emitting layer (included in the organic layer 204 in the embodiment) for each self-emitting device 102. Since the patterning with the use of the photolithography method is a known technology, the description thereof is omitted.

As shown in FIGS. 9A and 9B, the insulating film 103 is formed between the lower electrodes 201 patterned at the transparent conductive film patterning step. After forming the insulating film 103, an upper electrode partition 901 (upper electrode separator) may be formed for patterning the upper electrode 205. The upper electrode 205 may be patterned using a film forming mask (see FIG. 10) when a film is formed by an evaporation apparatus (see FIG. 10) described later without using the upper electrode partition 901, for example. After forming the insulating film 103, a UV (ultraviolet) cleaning step is performed for removing organic matters and moisture on the surface of the substrate 101. The first to fourth steps described above are the preprocessing step of the organic EL device manufacturing process.

The sipe 104 is subsequently formed in the insulating film 103 formed at the insulating film forming step. A sipe forming step is realized. With this sipe forming step, the sipe 104 dividing the insulating film 103 in the thickness direction of the insulating film 103 is formed on the outer side of the outermost self-emitting devices 102a in the array surface of the self-emitting devices 102 on the substrate 101.

At the sipe forming step, the sipe 104 may be formed by cutting the insulating film 103 with a blade such as a rotary cutter or the sipe 104 may be formed by cutting the insulating film 103 with a laser beam. At the sipe forming step, for example, if the sipe 104 is formed with a blade, when forming the sipe 104 completely dividing the insulating film 103 along the direction opposed to the substrate 101 and the sealing member 206, the insulating film is cut until a blade edge reaches to the substrate.

At the sipe forming step, for example, if the sipe is formed with a blade, when forming the sipe 104 as shown in FIG. 3 partially dividing the insulating film 103 along the direction opposed to the substrate 101 and the sealing member 206, the insulating film 103 is cut short of reaching to the substrate.

At the sipe forming step, for example, if a plurality of sipes (e.g., the first sipe 401 and the second sipe 402, or the first sipe 501 and the second sipe 502) are formed along the outward direction in the array surface of the self-emitting devices 102, the same operation is repeated for a plurality of times. At the sipe forming step, for example, if a plurality of sipes (e.g., the first sipe 401 and the second sipe 402, or the first sipe 501 and the second sipe 502) is formed with different depths in the direction opposed to the substrate and the sealing member, the same operation is repeated for a plurality of times in accordance with the shapes of the sipes that will be formed.

The sipe 104 may be formed concurrently with the formation of the insulating film 103 in the patterning of the insulating film 103 using the photolithography method by adjusting a pattern of a light shielding material (mask) used when exposing a photosensitive agent (photoresist) applied to the substrate 101. In this case, the sipe forming step is realized concurrently with the insulating film forming step.

After the preprocessing step using FIG. 6 to FIG. 9B is completed, a film forming step is performed using the evaporation apparatus described in FIG. 10. FIG. 10 shows the evaporation apparatus used at the film forming step. An evaporation apparatus 1000 is composed of a chamber (film forming chamber) connected to a valve 1001. The chamber 1002 is provided with a heating unit 1003, a magnet unit 1004, a film forming mask 1005, and a film forming monitor 1006. The substrate 101 formed at the first to fourth steps described above is carried into the evaporation apparatus 1000 and located steadily on the upper portion of the film forming mask 1005 in the chamber (film forming chamber) maintained in a vacuum state.

The substrate 101 and the film forming mask 1005 are attached closely to each other by the magnet unit 1004. When forming a film, an evaporation source 1007 is disposed at the heating unit 1003, and the film forming mask 1005 supported by a mask frame not shown is placed above the evaporation source 1007.

A film forming material 1008 is sublimated or evaporated into a gaseous form by heating the evaporation source 1007 with the heating unit 1003, and the gaseous film forming material 1008 is deposited on the substrate 101 to form the organic layer 204 or the upper electrode 205. The film forming step using such an evaporation apparatus 1000 to form the organic layer 204 or the upper electrode 205 can be applied to any organic materials or electrode materials that may be used for the organic EL device.

As described above, the organic layer 204 is formed by stacking the hole transporting layer, the emitting layer, the electron transporting layer, etc. in a single or composite structure. When forming a film of the organic layer 204, various organic materials such as CuPc, NPB, and Alq₃ can be applied. If the organic EL devices are used for the self-emitting devices 102 in a self-emitting panel displaying a plurality of luminescent colors, the organic layer 204 can be formed in various patterns. When the organic layer 204 is formed, the hole transporting layer, the electron transporting layer, etc. may be formed with film thicknesses corresponding to luminescent colors. With the preprocessing step and the film forming step described above, a plurality of the self-emitting devices 102 are formed on the substrate 101.

After the film forming step using the evaporation apparatus shown in FIG. 10, the substrate 101 is carried from the vacuum atmosphere to a sealing chamber (not shown) subjected to an inert gas atmosphere of N₂. Before carrying the substrate 101 into the sealing chamber, a luminescence inspection may be performed for inspecting whether the formed self-emitting devices 102 have the desired luminance or not.

After the film forming step using the evaporation apparatus 1000 shown in FIG. 10 is completed, a sealing step (not shown) is performed. In addition to the formation of the self-emitting devices 102 described above, the sealing member is created which is provided with a concave portion by blast processing. In the sealing member 206, the desiccant 209 such as SrO, CaO, BaO is placed in the concave portion. When the substrate 101 is carried into the sealing chamber, the sealing member 206 is also carried into the sealing chamber. The desiccant 209 may be the desiccant 209 in a form of a powdered material fixed inside the sealing member 206 with a protective sheet, the desiccant 209 processed into a sheet shape, or the desiccant 209 fixed by curing a liquid drying material applied in the sealing member 206.

The adhesive agent 207 is then applied to a place corresponding to a flange portion of the sealing member 206 on the substrate 101. For example, the adhesive agent 207 can be an adhesive agent made of a UV curing epoxy resin. When the adhesive agent 207 is applied, a dispenser may be used for the application.

The substrate 101 with the adhesive agent 207 applied is bonded to the sealing member 206 via the adhesive agent 207. Ultraviolet light is then irradiated to the adhesive agent 207 from the direction of the substrate 101. In this way, the adhesive agent is cured and the substrate 101 and the sealing member 207 are bonded via the adhesive agent 207. In the embodiment, the sealing step is realized at this point. With this sealing step, the sealing region 208 is formed with the substrate 101 to shield the self-emitting devices 102 from the air.

In the sealing step, the sealing member 206 is bonded to the substrate 101 such that a gap through the adhesive agent 207 is not created between the sealing member 206 and the substrate 101. By bonding the substrate 101 and the sealing member 206 with the use of the adhesive agent 207 in this way, the sealing region can be completely shielded from the air. As a result, the aforementioned self-emitting panel (organic EL panel) can be obtained. In addition to the air-tight sealing described in the embodiment, the sealing region 208 may be sealed by using sealing methods such as solid sealing or film sealing in the sealing step.

As described above, according to the self-emitting panel 100 of the embodiment, since the sipe 104 is provided at the outer side of the outermost self-emitting devices 102a in the array surface of the self-emitting devices 102 to divide the insulating film 103 along the direction opposed to the substrate 101 and the sealing member 206, if the deterioration factor such as the moisture contained in the air enters into the sealing region 208 through the adhesive agent 207, the sipe 104 can inhibit the deterioration factor from being delivered through the insulating film 103.

According to the self-emitting panel 100 of the embodiment, by forming the sipe 104 in a shape that completely divides the insulating film 103 along the direction opposed to the substrate 101 and the sealing member 206, the sipe 104 can adequately block the deterioration factor from being delivered through the insulating film 103.

According to the self-emitting panel 100 of the embodiment, by forming the sipe 104 in a shape that partially divides the insulating film 103 along the direction opposed to the substrate 101 and the sealing member 206, the sipe 104 can inhibit the deterioration factor from being delivered through the insulating film 103 by narrowing the region where the deterioration factor is delivered through the insulating film 103 without reducing the bonded area of the insulating film 103 to the substrate 101.

If a plurality of the sipes 104 are provided along the outward direction in the array surface of the self-emitting devices 102 in the self-emitting panel 100 in the embodiment, the plurality of the sipes 104 can effectively inhibit the deterioration factor from being delivered through the insulating film 103.

For example, as shown by the self-emitting panel 400 or 500, if a plurality of sipes (e.g., the first sipe 401 and the second sipe 402, or the first sipe 501 and the second sipe 502) are formed with different depths in the direction opposed to the substrate and the sealing member, the sipes in each shape can exert a plurality of effects to inhibit the deterioration factor from being delivered through the insulating film 103.

For example, if the self-emitting panel is provided with the sipe 104 at the outer side of the self-emitting device 102a provided at a position having a shortest distance from the bonding area 105 in the array surface of the self-emitting devices 102, the deterioration can be effectively prevented in the self-emitting devices 102 most susceptible to the deterioration factor.

For example, if the self-emitting panel is provided with the sipe 104 at the outer side of the self-emitting device 102a provided at a position having a distance from the bonding area 105 shorter than a predetermined distance among the outermost self-emitting devices 102a in the array surface of the self-emitting devices 102, the deterioration can be effectively prevented in the self-emitting devices 102 susceptible to the deterioration factor.

According to the self-emitting panel 100 of the embodiment, by realizing the self-emitting devices 102 with the organic EL devices, the performance deterioration can be prevented in the self-emitting panel using the organic EL devices susceptible to the moisture contained in the air.

According to the manufacturing method of the self-emitting panel 100 of the embodiment, since the sipe forming step is included for forming the sipe 104 dividing the insulating film 103 along the thickness direction of the insulating film 103 at the outer side of the outermost self-emitting devices 102a in the array surface of the self-emitting devices 102 in the insulating film 103 formed with the insulating film forming step, the self-emitting panel 100 with the aforementioned sipe 104 can be created without significantly changing the steps as compared to the manufacturing method of the conventional self-emitting devices (see FIG. 12).

According to the manufacturing method of the self-emitting panel of the embodiment, only the depth of the sipe along the direction opposed to the substrate 101 and the sealing member 206 is needed to be adjusted for the sipe completely dividing the insulating film 103 along the direction opposed to the substrate 101 and the sealing member 206 (e.g., the sipe 104, the first sipe 401, and the second sipe 502) and the sipe partially dividing the insulating film 103 along the direction opposed to the substrate 101 and the sealing member 206 (e.g., the sipe 301, the second sipe 402, and the first sipe 501), the self-emitting panel with the aforementioned sipe can be formed without considerably changing the details of the sipe forming step depending on the shape of the sipe that will be formed.

Similarly, according to the manufacturing method of the self-emitting panel of the embodiment, if a plurality of sipes (e.g., the first sipe 401 and the second sipe 402, or the first sipe 501 and the second sipe 502) are formed at the sipe forming step, the self-emitting panel with the aforementioned sipes can be formed without considerably changing the details of the sipe forming step depending on the number of the sipes that will be formed.

In consideration of above, according to the manufacturing method of the self-emitting panel of the embodiment, if a plurality of sipes (e.g., the first sipe 401 and the second sipe 402, or the first sipe 501 and the second sipe 502) are formed with different depths in the direction opposed to the substrate 101 and the sealing member 206 at the sipe forming step, the self-emitting panel with the aforementioned sipes can be formed without considerably changing the details of the sipe forming step depending on the number or shapes of the sipes that will be formed.

According to the manufacturing method of the self-emitting panel of the embodiment, at the sipe forming step, if the sipe 104 is formed at the outer side of the self-emitting device 102a provided at a position having a shortest distance from a bonding position of the substrate 101 and the sealing member 206 (i.e., the bonding area 105) or if the sipe 104 is formed at the outer side of the self-emitting device 102a provided at a position having a distance from the bonding position of the substrate 101 and the sealing member 206 (i.e., the bonding area 105) shorter than a predetermined distance, the self-emitting panel with the aforementioned sipe can be formed without considerably changing the details of the sipe forming step depending on the position where the sipe will be formed.

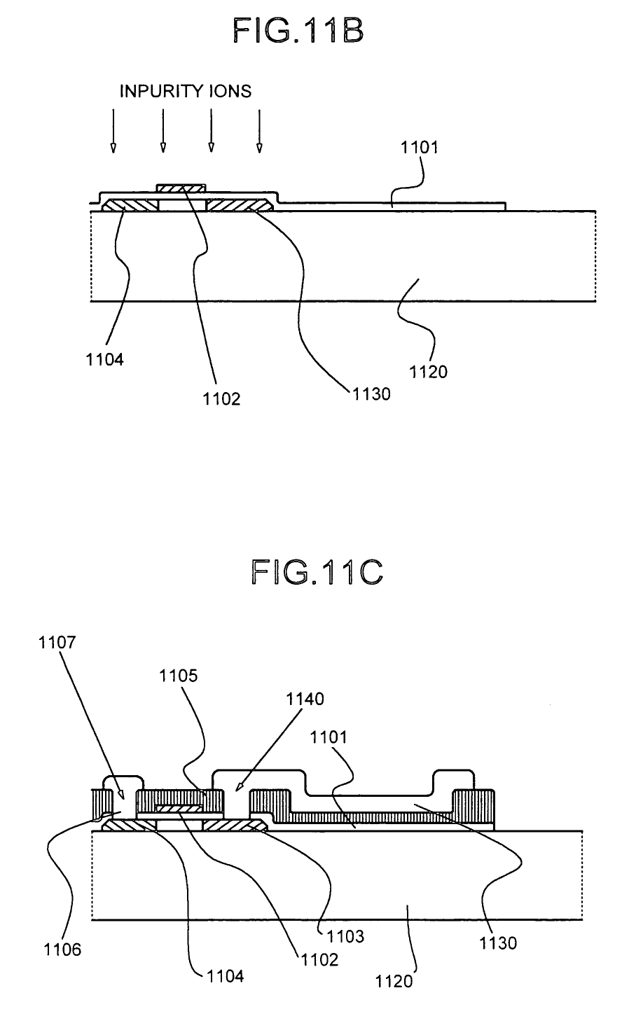

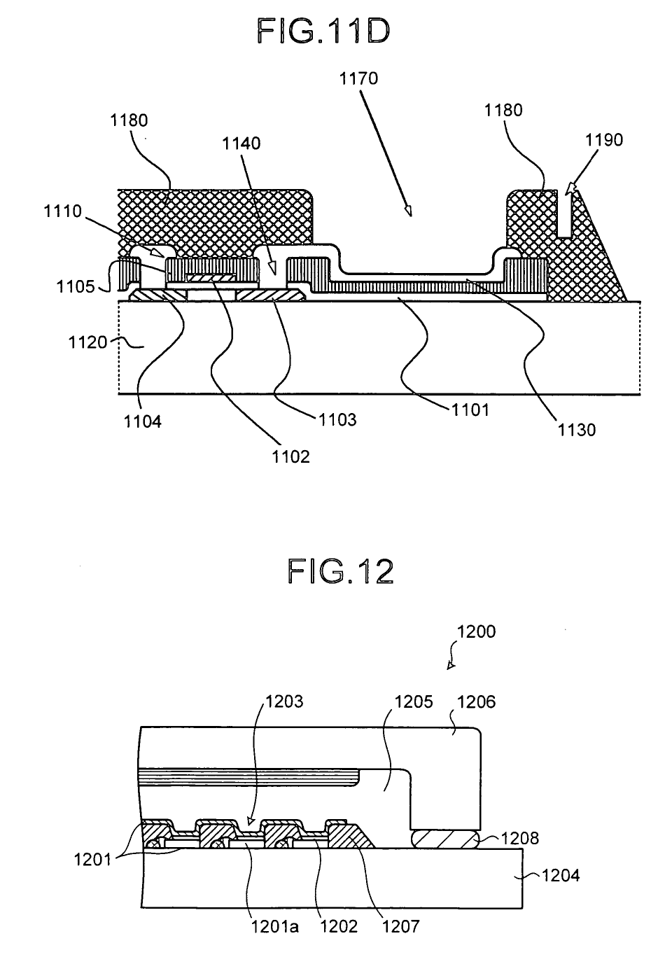

FIG. 11A is a cross-section of a self-emitting panel according to another embodiment of the present invention. FIG. 11A shows an example of an active drive self-emitting panel. The embodiments are not limited to the passive drive self-emitting panel 100 (the self-emitting panel 300, the self-emitting panel 400 or the self-emitting panel 500) and may be the active drive self-emitting panel 1100.

The active drive self-emitting panel 1100 is provided with a TFT 1110 formed by a gate insulating film 1101, a gate electrode 1102, a drain electrode 1103, a source electrode 1104, and an interlayer insulating layer 1105. The TFT 1110 is placed on a substrate 1120. The drain electrode 1102 and a lower electrode 1130 are electrically connected through a contact hole 1140. On the lower electrode 1130, an organic layer 1150 and an upper electrode 1160 are sequentially stacked and a self-emitting device (organic EL device) 1170 is provided.

The single organic EL device 1170 or a plurality of the organic EL devices 1170 are formed on the substrate 1120. Each pixel (luminous, emitting) area of the self-emitting device 1170 is formed by an insulating film 1180 in the self-emitting panel 1100. As described above, a sipe 1190 is formed in the insulating film 1180 at the outer side of the outermost self-emitting device (organic EL device) 1170a in the array surface of the self-emitting devices 1170.

The manufacturing process of the self-emitting panel 1100 is composed of a preprocessing step, a film forming step, and a sealing step using the sealing member 206. Since the film forming step and the sealing step of the second manufacturing method of the self-emitting panel are the same steps as the first manufacturing method of the self-emitting panel described above, only the preprocessing step is described here. The preprocessing step of the manufacturing process of the self-emitting panel 1100 includes a TFT forming step, a lower electrode forming step, and an insulating film forming step.

FIG. 11B is a cross-section for illustrating a process of forming the TFT. At the TFT forming step, a p-Si film is formed by laser annealing on the substrate 1120. The formed p-Si film is patterned by an ultraviolet light excimer laser and subsequently, silicon nitride, etc. are provided by the CVD method to form the gate insulating film 1101.

Patterning is then performed by etching a material film with a polycide structure constituted by stacking a polysilicon film formed by the CVD method and a metal silicide film formed by the sputtering method or the CVD method. When the etching is performed, the film is masked by a resist pattern formed by the lithography method. In this way, the gate electrode 1102 is formed.

After forming the gate electrode 1102, impurities are injected into the gate electrode 1102 by the ion doping method. In this way, the drain electrode 1103 and the source electrode 1104 are formed.

FIG. 11C is a cross-section for illustrating a process of forming the lower electrode. At the lower electrode forming step, the interlayer insulating layer 1105 is formed on the substrate 1120 to cover the gate electrode 1102, the drain electrode 1103, and the source electrode 1104. The interlayer insulating layer 1105 is made of a silicon oxide material such as silicon oxide.

Exposure and development are performed to form a contact hole 1107 of the source electrode 1104 and a data line 1106 and the contact hole 1140 of the drain electrode 1103 and the lower electrode 1130. After forming the contact holes 1107, 1140 as above, the data line 1106 and the lower electrode 1130 is patterned and formed by sputtering, etc. with Al, etc. and ITO, etc., respectively.

FIG. 11D is a cross-section for illustrating a process of forming the insulating film. At the insulating film forming step, an insulating film is formed on the lower electrode 20 by forming a film of polyimide, etc. with the use of the spin-coating. The photolithography method is then used to perform patterning to open a portion where the organic EL device 1170 is formed. The sipe 1190 is formed by using the photolithography method in the outer portion of the insulating film 1180 in contact with the outermost organic EL device 1170a (see FIG. 11A).

As described above, according to the manufacturing method of the self-emitting panel 1100 of the embodiment, when the insulating film 1180 is formed at the insulating film forming step, the sipe 1190 can be formed concurrently with the formation (patterning) of the insulating film 1180. In this way, the self-emitting panel 1100 with the sipe 1190 can be manufactured without increasing the number of steps.

According to the manufacturing method of the self-emitting panel 1100 of the embodiment, in addition to the various effects of the various self-emitting panels 100, 300, 400, 500, the steps for forming the sipe 1190 can be simplified.

The present document incorporates by reference the entire contents of Japanese priority document, 2005-061646 filed in Japan on Mar. 4, 2005.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A self-emitting panel comprising:
a plurality of self-emitting devices arranged in an array and including
a pair of electrodes; and
an emitting layer arranged between the electrodes;
a substrate on which the self-emitting devices are provided;
an insulating film provided on the substrate, and configured to insulate each of the self-emitting devices from others of the self-emitting devices on the substrate, by separating a set of the emitting layer and at least one of the electrodes from each set of the emitting layer and at least one of the electrodes of the others;
a sealing member arranged on the substrate such that a sealing region is formed between the sealing member and the substrate, the sealing region for shielding the self-emitting devices from the air; and
a sipe provided on a surface of the substrate on which the self-emitting devices are arranged at a portion beside an outermost self-emitting device that is arranged at an outermost part in the array such that the sipe is positioned closer to an edge of the substrate than the outermost self-emitting device is, the sipe having a depth in a direction in which the substrate and the sealing member are opposed, to divide the insulating film.

2. The self-emitting panel according to claim 1, wherein the sipe is provided so as to completely separate the insulating film.

3. The self-emitting panel according to claim 1, wherein the sipe is provided so as to separate the insulating film halfway.

4. The self-emitting panel according to claim 1, wherein the sipe is provided in plurality along a direction toward the edge of the substrate from the array.

5. The self-emitting panel according to claim 4, wherein each sipe has a different depth.

6. The self-emitting panel according to claim 1, wherein
the sealing member is bonded to the substrate, and
the portion at which the sipe is provided is beside a self-emitting device provided at a position having a shortest distance from a position at which the sealing member is to be bonded, from among the self-emitting devices in the array.

7. The self-emitting panel according to claim 1, wherein
the sealing member is bonded to the substrate, and
the portion at which the sipe is provided is beside a self-emitting device provided at a position having a distance shorter than a predetermined distance from a position at which the sealing member is to be bonded, from among the self-emitting devices in the array.

8. The self-emitting panel according to claim 1, wherein the outermost self-emitting device includes a monitor device.

9. The self-emitting panel according to claim 1, wherein the self-emitting device includes an organic electroluminescence device.

10. A method of manufacturing a self-emitting panel comprising:
arranging a plurality of self-emitting devices on a substrate in an array, the self-emitting devices each including a pair of electrodes, and an emitting layer arranged between the electrodes;
forming an insulating film on the substrate, the insulating film configured to insulate each of the self-emitting devices from others of the self-emitting devices on the substrate, by separating a set of the emitting layer and at least one of the electrodes from each set of the emitting layer and at least one of the electrodes of the others;
forming a sipe on a surface of the substrate on which the self-emitting devices are arranged at a portion beside an outermost self-emitting device that is arranged at an outermost part in the array such that the sipe is positioned closer to an edge of the substrate than the outermost self-emitting device is, the sipe having a depth in a direction of a thickness of the insulating film, to divide the insulating film; and
forming a sealing region for shielding the self-emitting devices from the air, between a sealing member and the substrate by providing the sealing member on the substrate.

11. The method according to claim 10, wherein the forming a sipe includes forming the sipe so as to completely separate the insulating film.

12. The method according to claim 10, wherein the forming a sipe includes forming the sipe is provided so as to separate the insulating film halfway.

13. The method according to claim 10, wherein the forming a sipe includes forming the sipe in plurality along a direction toward the edge of the substrate from the array.

14. The method according to claim 13, wherein each sipe has a different depth.

15. The method according to claim 10, wherein
the forming a sealing region includes bonding the sealing member to the substrate, and
the forming a sipe includes forming the sipe at a portion beside a self-emitting device provided at a position having a shortest distance from a position at which the sealing member is to be bonded, from among the self-emitting devices in the array.

16. The method according to claim 10, wherein
the forming a sealing region includes bonding the sealing member to the substrate, and
the forming a sipe includes forming the sipe at a portion beside a self-emitting device provided at a position having a distance shorter than a predetermined distance from a position at which the sealing member is to be bonded, from among the self-emitting devices in the array.

17. The method according to claim 10, wherein the outermost self-emitting device includes a monitor device.

18. The method according to claim 10, wherein the self-emitting device includes an organic electroluminescence device.
